(19) United States
(12) Patent Application Publication
(10) Pub. No.: US 2005/0018403 A1
(43) Pub. Date: Jan. 27, 2005

(54) BGA ball vision enhancement

(76) Inventors: Chong Seng Foo, Penang (MY); Booh Keat Yeoh, Penang (MY); Kok Kuan Gan, Kedah (MY)

Correspondence Address: Stephen M. De Klerk;BLAKELY, SOKOLOFF, TAYLOR & ZAFMAN LLP, Seventh Floor, 12400 Wilshire Boulevard, Los Angeles, CA, 90025, US

(21) Appl. No.: 10/607,074

(22) Filed: Jun. 25, 2003

(51) Int. Cl. H05K 7/20

(52) U.S. Cl. 361/719

(57) ABSTRACT

According to one aspect of the invention, a method and apparatus for handling semiconductor packages is provided. The semiconductor packages include package substrates with a plurality contact formations on a bottom surface thereof. The packages are fed into a handling machine, which includes a CCD camera. The contact formations are imaged by the CDD camera after the semiconductor packages are picked from the feeder. The captured image is relatively low resolution and is made of relatively large pixels. A computer approximates a center of the contact formations based on the captured images and places the packages on a circuit board in the handling machine.

### BACKGROUND OF THE INVENTION

1). Field of the Invention

This invention relates to a method of processing semiconductor packages and a machine used in such a method.

2). Discussion of Related Art

Integrated circuits are formed on semiconductor wafers, which are then sawed into individual semiconductor chips, also known as microelectronic dies. Each resulting die is then packaged on a package substrate. The package substrate has a number of Ball Grid Array (BGA) solder ball contact formations on an opposing side, which are electrically connected to the integrated circuit through the package substrate. The package is then placed in a handling machine, which places the package in a socket on a circuit board.

In order to accurately place such a package, the contact formations are imaged by a high resolution camera, such as a Line Scan Camera, to determine the center points of the formations.

The image of the contact formations captured by the camera may not be of the entire contact formation, due to differences in the brightness of different areas of the contact formation. This effect can be magnified by imperfections on the contact formations caused by exposure to various gases during processing and even exposure to the atmosphere. Additionally, the brightness of the light reflected by the contact formation or the sensitivity of the camera may have to be adjusted due to different brightnesses of contact formations from different suppliers.

The high resolution and small pixels of the image often cause the handling machine to inaccurately approximate the center of the contact formation because the captured image is not of the entire contact formation, resulting in incorrect placement of the package.

### BRIEF DESCRIPTION OF THE DRAWINGS

The invention is described by way of example with reference to the accompanying drawings, wherein:

FIG. 1 is a perspective view of a microprocessor, including a package substrate with a plurality of contact formations on a bottom surface thereof;

FIG. 2 is a bottom view of the microprocessor;

FIG. 3 is a bottom view of a contact formation;

FIG. 4 is a top plan view of a system for handling semiconductor packages, including a pick and place head, a feeder, a CDD camera, and a circuit board;

FIGS. 5a-5c are side views of the system for handling semiconductor packages illustrating picking the microprocessor from the feeder (FIG. 5b) and suspending the microprocessor over the CDD camera (FIG. 5c);

FIGS. 6a-6c are representative of images of the contact formation captured by the CDD camera illustrating pixel selection (FIG. 6b) and determination of a captured image center (FIG. 6c);

FIG. 7 is representative of a prior art processing of an image of a contact formation captured by a prior art Line Scan Camera, including pixel selection and determination of a captured image center; and

FIGS. 8a and 8b are side views of the system for handling microelectronic dies illustrating placement of the microprocessor on the circuit board (FIG. 8a) and resetting of the system.

### DETAILED DESCRIPTION OF THE INVENTION

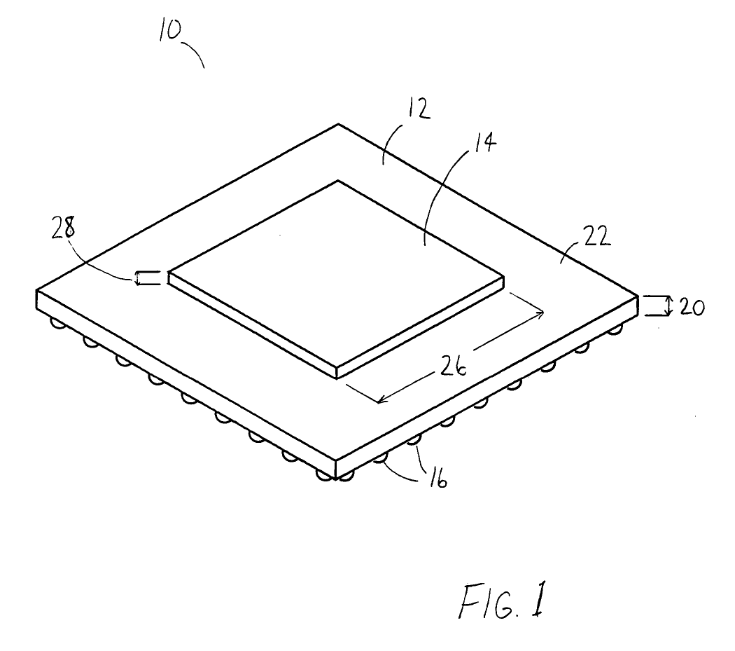

FIG. 1 to FIG. 8b illustrate a method and apparatus for handling semiconductor packages. The semiconductor packages include package substrates with a plurality contact formations on a bottom surface thereof. The packages are fed into a handling machine, which includes a Charged Coupled Device (CCD) camera. The contact formations are imaged by the CCD camera after the semiconductor packages are picked from the feeder. The captured image is relatively low resolution and is made of relatively large pixels. A computer approximates a center of the contact formations based on the captured image and places the packages on a circuit board in the handling machine.

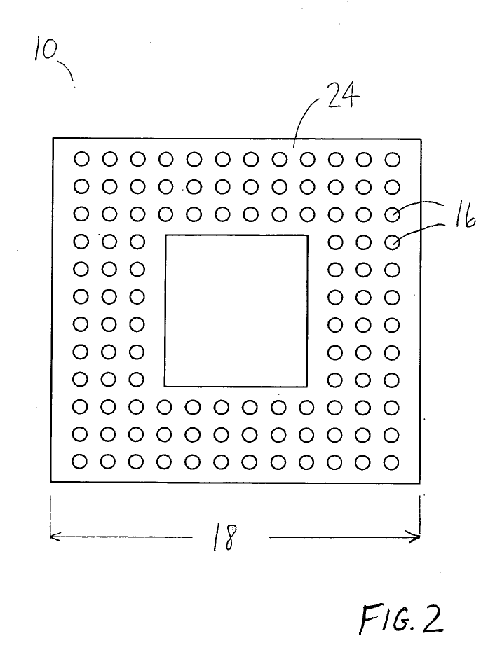

FIGS. 1 and 2 illustrate a typical semiconductor package 10, in the form of a microprocessor, which includes a package substrate 12, a microelectronic die 14, and a plurality of contact formations 16.

The package substrate 12 is square with side lengths 18 of 3 cm and a thickness 20 of 3 mm. The package substrate 12 has a top 22 and a bottom 24 surface and a plurality of alternating conducting and insulating layers therein, as is commonly understood in the art.

The microelectronic die 14 is mounted on the top surface 22 of the package substrate 12 at a central portion thereof. The microelectronic die 14 is square with side lengths 26 of 1.5 cm and a thickness 28 of 1000 microns. The microelectronic die 14 includes an integrated circuit formed therein and a plurality of alternating insulating and conducting layers, as is commonly understood in the art.

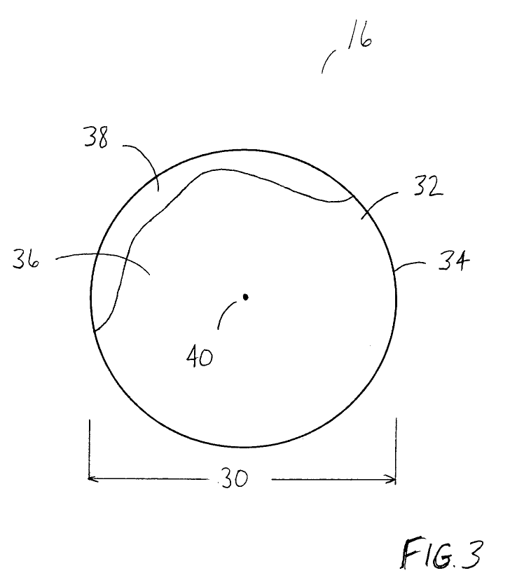

FIG. 2 illustrates the bottom surface 24 of the package substrate 12. The contact formations 16 are BGA solder balls secured to the bottom surface 24 of the package substrate 12 and cover the entire bottom surface 24 except for a square central portion thereof. FIG. 3 illustrates one of the contact formations 16 as it actually appears from beneath the package 10. The contact formations 16 are substantially spherical, stand proud of the bottom surface 24, and have diameters 30 of 0.55 mm. The contact formations 16 are made of solder and are electrically connected to the integrated circuit within the microelectronic die 14 through the package substrate 12.

As shown in FIG. 3, the contact formation 16 as it actually appears has a surface 32 which includes an outer edge 34, a first area 36, a second area 38, and an actual center 40, or actual contact point. The first area 36 is a normal brightness area, and the second area 38 is a dull brightness area. The dull brightness area 38 occupies a portion of an outer region of the surface 32 of the contact formation 16 and is relatively small, as the normal brightness area 36 occupies the majority of the surface 32 of the contact formation 16.

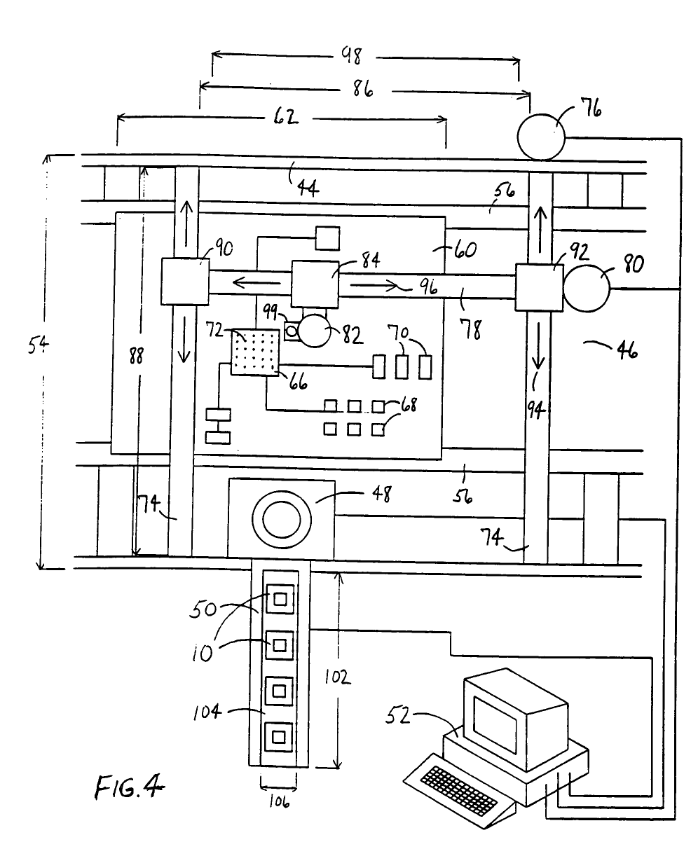

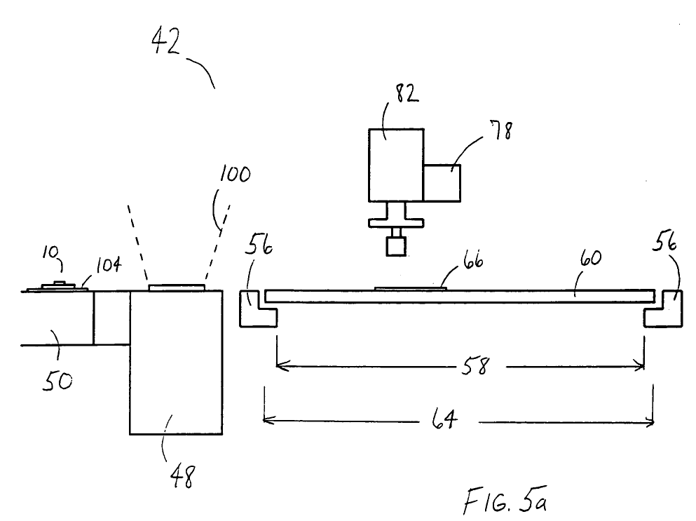

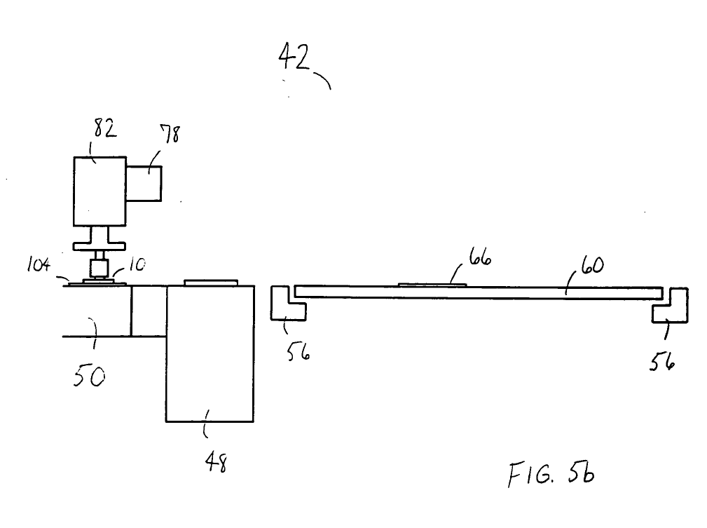

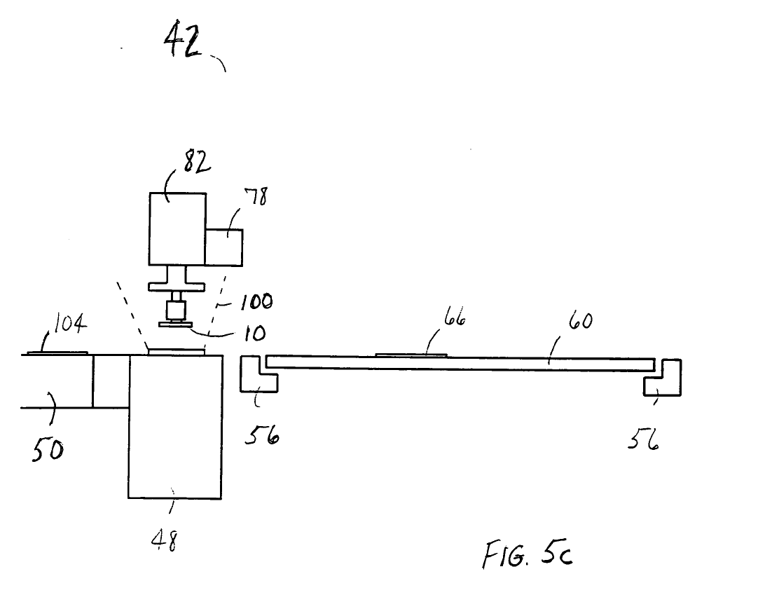

FIGS. 4 and 5a illustrate a system 42 for handling semiconductor packages. The system 42 for handling semiconductor packages includes a frame 44, a pick-and-place subsystem 46, a CCD camera 48, a feeder 50, and a computer control console 52.

The frame 44 has a width 54 of 800 mm and includes two rails 56 secured parallel to each other at an inner portion thereof. The rails 56 are mounted to the frame 44 at a distance 58 of 400 mm apart and shaped to secure a printed circuit board, such as a motherboard.

A motherboard 60 is placed within the rails 56 and is supported so that is may slide along the rails 56. The motherboard 60 is rectangular with a length 62 of 600 mm and a width 64 of 400 mm and is made of silicon. The motherboard includes a primary socket 66, a plurality of secondary sockets 68, and a plurality of semiconductor chips 70 located in the secondary sockets. Although not shown in detail, the motherboard 60 has several alignment marks, typically fiducials, and the primary socket 66 includes a number of conductive pads 72, one for each contact formation 16, as is commonly understood in the art.

The pick-and-place subsystem 46 includes two Y-arms 74, a Y-direction motor 76, an X-arm 78, an X-direction motor 80, a pick-and-place head 82, and a pick-and-place head motor 84. The Y-arms 74 are mounted to the frame 44 at opposing ends thereof and extend over the rails at a distance 86 of 600 mm apart. The Y-arms 74 have a length 88 of 800 mm. The X-arm 78 is connected to the Y-arms 74 at opposing ends thereof by first 90 and second 92 XY-junctions which are mounted to the Y-arms 74 such that the X-arm 78 can translate in Y direction 94 between the Y-arms 74. The X-arm 78 extends over the rails 56 and the motherboard 60. The Y-direction motor 76 is mounted to the frame 44 and connected to the second XY-junction 92. The pick-and-place head 82 is mounted to the X-arm 78 and is suspended over the rails 56. The pick-and-place head 82 is mounted to the X-arm 78 so that it may translate in an X direction 96 between the Y-arms 74 along the X-arm 78 and move vertically towards and away from the motherboard 60. The X-direction motor 80 is mounted to the second XY-junction 92 and connected to the pick-and-place head 82. The X-arm 78 has a length 98 of 600 mm. The pick-and-place head motor 84 is housed within and secured to the pick-and-place head 82 and is connected to the X-arm 78. The pick-and-place head 82 has an alignment camera 99 mounted thereto, which faces directly down towards the motherboard 60.

The CCD camera 48 is mounted to a side of the frame 44. The CDD camera 48 has a field of view 100 with a focal length, which is directed upwards, as illustrated in FIG. 5a, at right angles to the X-arm 78 and the Y-arms 74. The CCD camera 48 includes a rectangular piece of silicon known as a charged coupled device which is segmented into an array of individual light sensitive cells called “photosites”, as is commonly understood in the art.

The feeder 50 is in the form of a reel and is secured to the frame 44 near the CCD camera 48. The feeder 50, when viewed from the top, is rectangular with a length 102 extending parallel to the Y-arms 74. An adhesive tape 104 is stretched over an upper surface of the feeder 50. The adhesive tape 104 has a width 106 of 3.5 cm. Numerous packages 10 are attached to the adhesive tape 104.

The computer control console 52 is electronically connected to the X-direction motor 80, the Y-direction motor 76, the pick-and-place head motor 84, the alignment camera 99, the CCD camera 48, and the feeder 50. The computer control console 52 is in the form of the computer having memory for storing a set of instructions in a processor connected to the memory for executing the instructions, as is commonly understood in the art.

In use, as illustrated in FIGS. 5a though 5c, when the motherboard 60 and a first package 10 are in position, the pick-and-place head 82 moves from its original position above the motherboard 60, in an X/Y coordinate system, to a position above the first package 10 on the feeder 50. The pick-and-place head 82 lowers to the tape 104 and picks the first package 10 from the tape 104. The pick-and-place head 82 returns to its original height and carries the first package 10 back toward the motherboard 60. As the pick-and-place head 82 moves over the CCD camera 48, it pauses briefly, suspending the bottom surface 24 of the package substrate 12 in the field of view 100 and at the focal length of the CDD camera 48. The CCD camera 48 then captures an image 108 of the contact formations 16 on the bottom surface 24 of the package substrate 12.

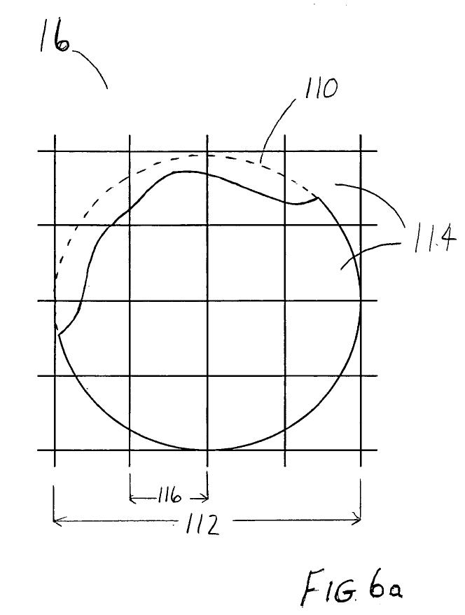

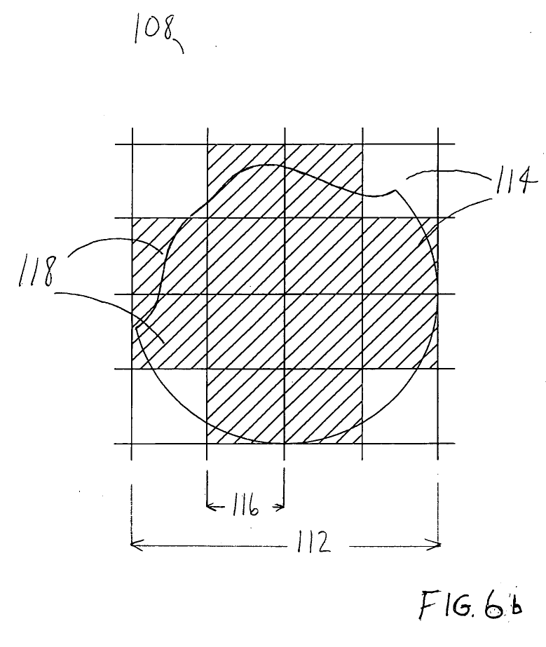

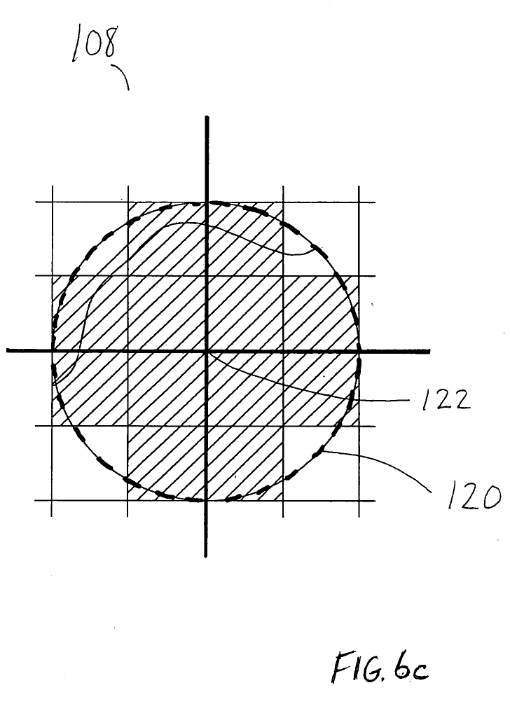

FIGS. 6a through 6c illustrate the creation of the captured image 108 of the contact formation 16 as seen by the CCD camera 48. As illustrated in FIG. 6a, only the normal brightness area 36 is detected, or captured, by the CCD camera. The dull brightness area 38 is not detected at all. The dotted line 110 in FIG. 6a illustrates where the outer edge 34 of the actual contact formation 16 would lie if the entire actual contact formation 16 including the dull brightness area 38 were detected by the CDD camera 48, in which case the contact formation seen through the CCD camera would be circular, like the actual contact formation 16.

Each photosite of the charged coupled device generates one picture element or “pixel” 114 of the captured image 108. Thus, as shown, the captured image 108 has a width 112 and is broken into 16 pixels 114. Each pixel 114 is square with side lengths 116 of, for example, 96 microns. As illustrated in FIG. 6b, after the image 108 is detected, the image 108 is sent to the computer control console 52, which determines whether or not a minimum threshold portion of the area of each pixel 114 is occupied by the normal brightness area 36 or whether not each pixel 114 has a minimum threshold brightness. The pixels 114 that the computer determines to have the minimum threshold become “selected” pixels 118 and form the captured CCD image 108. FIG. 6b illustrates the complete captured CCD image 108 consisting of the selected pixels 118. In this example, only four of the pixels 114, one at the each of the corners of the pixel array, have not been selected. As a result, the captured image 108, as a whole, takes a symmetric cross shape. The side length 116 of one of the pixels 114 is 25% of the width of the captured image 108, or of the diameter 30 of the contact formation 16, as seen through the CCD camera.

As illustrated in FIG. 6c, the computer control console 52 then approximates a circle 120 based on the shape of the selected pixels 118. In the example shown, because of the symmetric shape of the selected pixels 118, the approximated circle 120 lies directly over the outer edge 34 of the surface 32 of the actual contact formation 16.

The computer 52 then calculates a captured image center 122, or captured contact point. Referring again to FIG. 6c, the captured image center 122 lies directly over the actual center 40 of the actual contact formation 16. Thus, the computer 52 has accurately approximated the center of the contact formation 16 using the image 108 captured by the CDD camera 48.

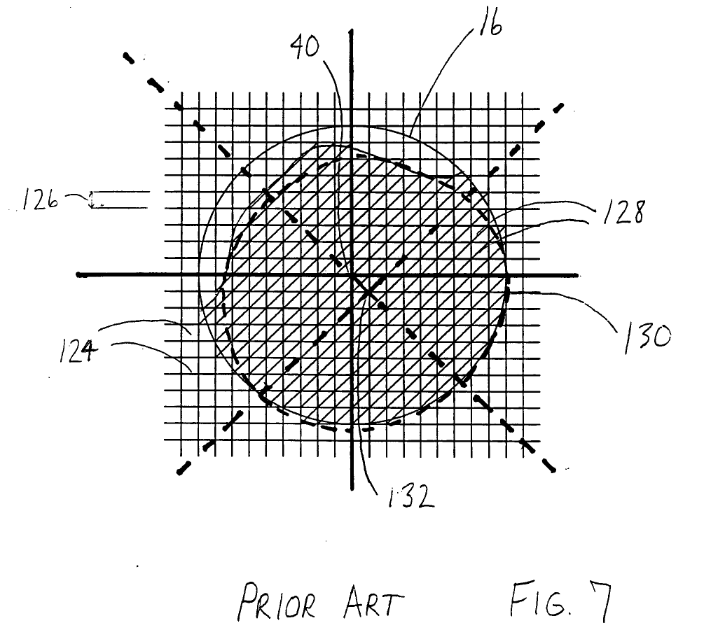

FIG. 7 illustrates an image of a contact formation 16 captured in a prior art method using a Line Scan Camera. The image captured by the Line Scan Camera comprises pixels 124 much smaller than the pixels 114 of the CCD camera 48 and have side lengths 126 of, for example, only 45 microns. As shown, because of the small pixel size, selected pixels 128 fill in an area that closely approximates the size and shape of the normal brightness of the contact formation, as only the normal brightness area is detected by the Line Scan Camera as well. Thus, as illustrated, the computer does a poor job of approximating the size, shape, and location of the contact formation when the approximated circle 130 is formed. Therefore, as illustrated, the approximated center 132 does not lie directly over the actual center 40 of the contact formation 16 as it does when the CCD camera 48 is used.

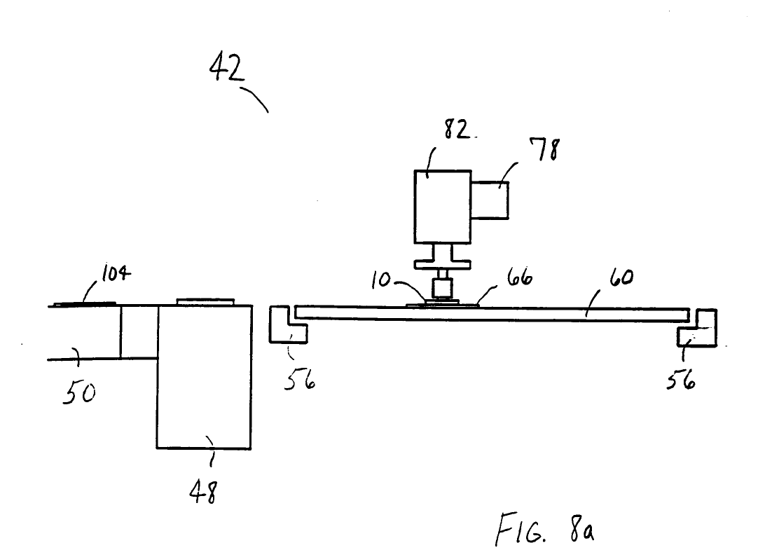

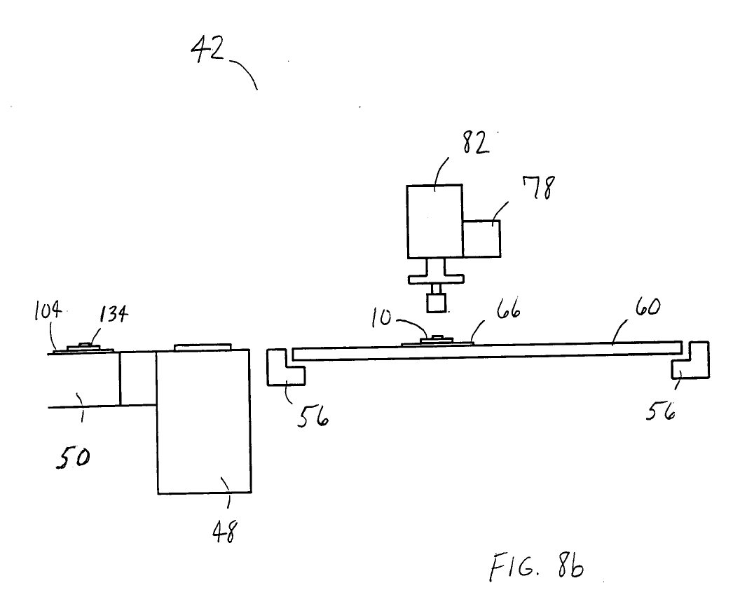

Returning to the present invention, FIGS. 8a and 8b illustrate the placement of the first package 10 into the socket 66. Referring to FIG. 8a, the pick-and-place head 82 carries the package 10 over the motherboard 60 and, after being properly aligned with the alignment marks on the motherboard 60, places the package 10 in the primary socket 66. Because of the accurate approximation of the actual center 40 of the contact formation 16, the computer 52 will accurately instruct the pick-and-place subsystem 46 in placing the package 10.

As illustrated in FIG. 8b, after the pick-and-place head 82 has placed the package 10 in the primary socket 66 on the motherboard 60, the pick-and-place head 82 returns to its original height so that the entire process may be repeated. The adhesive tape 104 on the feeder 50 has moved so that a second package 134 is now in position to be picked, and the motherboard 60 is slid out of the handling machine so that another may take its place. The entire process is then repeated for the second package 124 and the next motherboard.

One advantage of this system is that the semiconductor packages are more accurately placed on the circuit boards, resulting in improved, more reliable, and more consistent contact with the conductive pads in the socket. Another advantage is that neither the brightness of the actual contact formation nor the sensitivity of the camera needs to be adjusted when different BGA balls from different suppliers are used on the semiconductor packages.

Other embodiments of the invention may use a type of camera other than a CCD camera. Different numbers and sizes of pixels may be used, as long as the center of the approximated circle is directly over, or closer to the actual center of the contact formation than when using a high resolution camera, such as a Line Scan Camera. The image captured may be of more than one contact formation, so long as a similar ratio of the image size of each formation to the pixel size is maintained as described. The process may be used on different types of semiconductor packages besides microprocessors, which may have different types of contact formations.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. A method of processing an electronic assembly, comprising:
capturing an image of a contact formation on a surface of a semiconductor package, the semiconductor package including a microelectronic die with an integrated circuit formed therein, the image having a width and a captured contact point corresponding to an actual contact point on the contact formation and comprising a plurality of pixels, the pixels having side lengths of at least 20 percent of the width of the image; and
placing the semiconductor package on a circuit board having a socket such that the actual contact point is in a selected position relative to the socket.

2. The method of claim 1, further comprising picking the semiconductor package from a support.

3. The method of claim 2, further comprising suspending the surface of the semiconductor package within a field of view of the camera.

4. The method of claim 3, wherein the image is captured with a CCD camera.

5. The method of claim 4, wherein the contact formation has a surface comprising a first area and a second area.

6. The method of claim 5, where in the first area is a normal brightness area and the second area is a dull brightness area.

7. The method of claim 6, wherein the captured image includes only the normal brightness area of the outer surface of the contact formation.

8. The method of claim 7, wherein the contact formation has an outer edge and an actual center.

9. The method of claim 8, further comprising defining an outer edge of the captured image and determining a captured image center.

10. The method of claim 9, wherein the captured image center corresponds to the actual center of the contact formation.

11. The method of claim 10, wherein the contact formation is substantially spherical.

12. The method of claim 11, wherein there are a plurality of contact formations on the surface of the semiconductor package.

13. The method of claim 12, wherein the contact formations are BGA solder balls.

14. The method of claim 13, wherein the contact formation has a diameter of approximately 0.55 mm.

15. The method of claim 14, wherein the semiconductor package is a microprocessor.

16. The method of claim 15, wherein the circuit board is a motherboard.

17. The method of claim 16, wherein the socket has a plurality of conductor pads formed therein and when the semiconductor package is placed within the socket, the actual contact point of each contact formation contacts a conductor pad in the socket.

18. A method of processing an electronic assembly, comprising:
capturing an image of a contact formation on a surface of a semiconductor package with a CCD camera, the semiconductor package including a microelectronic die with an integrated circuit formed therein, the contact formation having a surface with an actual contact point, the image having an captured contact point corresponding to the actual contact point on the outer surface; and
placing the semiconductor package on a circuit board having a socket such that the actual contact point is in a selected position relative to the socket.

19. The method of claim 18, wherein the actual contact point is an actual center of the contact formation and the captured contact point is a captured center of the image.

20. The method of claim 19, wherein the semiconductor package is a microprocessor and the circuit board is a motherboard.

21. A method of processing a semiconductor package, comprising:
picking a microprocessor from a support, the microprocessor having a bottom surface with a plurality of contact formations formed thereon and including a microelectronic die with an integrated circuit formed therein, the contact formations being substantially spherical, each having a surface and being electrically connected to the integrated circuit, the surface having an actual center, a normal brightness, area, and a dull brightness area;
suspending the bottom surface of the microprocessor within a field a view of a CCD camera;
capturing an image of the normal brightness area of at least one of the contact formations with the CCD camera, the image having a width and a captured center and comprising a plurality of pixels, the captured center corresponding to the actual center, the pixels being square with sides of at least 20 percent of the width of the image; and
placing the microprocessor in a socket on a motherboard, the socket with a plurality of conductor pads formed therein, so that the actual center of each contact formation contacts a conductor pad within the socket and the integrated circuit is electrically connected to the conductor pads.

22. The method of claim 21, wherein the support is a reel with an adhesive tape attached thereto.

23. The method of claim 22, wherein the contact formations are BGA solder balls.

24. An apparatus for processing electronic assemblies, comprising:
a frame;
a semiconductor package support secured to the frame to support a semiconductor package, the semiconductor package having a surface with a contact formation thereon and including a microelectronic die with an integrated circuit formed therein;
a CCD camera, having a field of view, connected to the frame to capture an image of the contact formation;
a printed circuit board support secured to the frame to support a printed circuit board, the printed circuit board having a socket; and
a pick-and-place head connected to the frame for movement to pick the semiconductor package from the semiconductor package support, suspend the semiconductor package so that the surface of the semiconductor package is in the field of view of the CCD camera, and place the semiconductor package in the socket on the printed circuit board.

25. The apparatus of claim 24, wherein the CCD camera has a focal length and the pick-and-place head is connected to the frame such that it suspends the semiconductor package in the field of view of the CCD camera so that the surface of the semiconductor package is at the focal length of the CCD camera.

26. The apparatus of claim 25, wherein the support comprises an adhesive tape attached to a reel.

27. The apparatus of claim 26, wherein the circuit board is a motherboard.

28. The apparatus of claim 27, further comprising a computer in communication with communication with and coordinating the actions of the CCD camera and the pick-and-place head.
